(19) United States
(12) Patent Application Publication
(10) Pub. No.: US 2025/0329540 A1
(43) Pub. Date: Oct. 23, 2025

(54) METHOD FOR PROCESSING WAFER AND PROCESSING APPARATUS

(71) Applicant: DISCO CORPORATION, Tokyo (JP)

(72) Inventors: Ryo MIYAMA, Tokyo (JP); Masataka HIRASHIMA, Tokyo (JP); Takeshi DEJIMA, Tokyo (JP); Tomohiro YAMADA, Tokyo (JP)

(73) Assignee: DISCO CORPORATION, Tokyo (JP)

(21) Appl. No.: 19/176,605

(22) Filed: Apr. 11, 2025

(30) Foreign Application Priority Data
Apr. 19, 2024 (JP) 2024-067866

(51) Int. Cl. H01L 21/3065; B24B 49/04; H01L 21/67

(52) U.S. Cl. CPC H01L 21/3065; B24B 49/04; H01L 21/67253

(57) ABSTRACT

A method for processing a wafer into a preset thickness form by emitting a plasma-activated etching gas from an emitter toward one side of the wafer to etch the one side of the wafer includes a thickness distribution obtaining step including obtaining a thickness distribution of an entire surface on the one side of the wafer, a calculating step including calculating a position where the emitter emits the etching gas toward the wafer and an emitting amount of the etching gas to be emitted at the emitting position based on a difference between the thickness distribution obtained in the thickness distribution obtaining step and a preset finishing thickness distribution, and an etching step including emitting the etching gas of the etching amount at the etching position toward the one side of the wafer and etching the one side of the wafer to the preset thickness form.

### CROSS REFERENCE TO RELATED APPLICATION

This application is based upon and claims the benefit of priority from the prior Japanese Patent Application No. 2024-067866 filed on Apr. 19, 2024; the entire contents of which are incorporated herein by reference.

### FIELD

The present disclosure relates to a method and a processing apparatus for processing a wafer to an even thickness.

### BACKGROUND

Japanese Patent Laid-Open Publication No. 2013-119123 discloses a grinding apparatus for grinding a wafer, in which a chuck table holding the wafer is operated to rotate, and grindstones arranged annularly on a grinding wheel are operated to rotate and contact the wafer. The grinding apparatus may adjust an inclination of the chuck table with respect to the grindstones so that the wafer is ground to a preset even thickness distribution.

Moreover, Japanese Patent Laid-Open Publication No. 2015-223636 discloses a polishing apparatus, in which a wafer and a polishing pad being in contact with each other are rotated, to polish the wafer. The polishing apparatus may measure a thickness distribution in a radial direction of the wafer, and based on the measured thickness distribution, the polishing pad dressed by a dressing device may polish the wafer to a preset even thickness distribution.

### SUMMARY

According to the known technics, the wafer may be ground or polished in order to machine the wafer to an even thickness. Therefore, if the wafer is formed to be thicker locally in a circumferential direction or in a radial direction, due to the uneven thickness distribution, it may be difficult to grind the thicker part to the same thickness as the other part of the wafer.

Furthermore, in order to grind the thicker part to the preset thickness, the other part of the wafer may be ground to be thinner than the preset thickness; or in order to grind the other part to the preset thickness, the thicker part may be thicker than the preset thickness. As such, once the wafer is formed to have a locally thicker part, it may be difficult to remove the thickness difference from the wafer.

In view of the difficulty, one of the objects of the present disclosure is to provide a method for processing a wafer and a processing apparatus, by which a wafer having unevenness with a thicker part may be formed into a preset finishing thickness distribution.

According to an embodiment of the present disclosure, a method for processing a wafer into a preset thickness form by emitting a plasma-activated etching gas from an emitter toward one side of the wafer to etch the one side of the wafer includes a thickness distribution obtaining step including obtaining a thickness distribution of an entire surface on the one side of the wafer, a calculating step including calculating a position where the emitter emits the etching gas toward the wafer and an emitting amount of the etching gas to be emitted at the emitting position based on a difference between the thickness distribution obtained in the thickness distribution obtaining step and a preset finishing thickness distribution, and an etching step including emitting the etching gas of the etching amount at the etching position, the etching amount and the etching position having been calculated in the calculating step, toward the one side of the wafer and etching the one side of the wafer to the preset thickness form.

According to another aspect of the present disclosure, a processing apparatus includes a chuck table configured to hold a wafer, an emitter configured to emit a plasma-activated etching gas to etch the wafer held on the chuck table, a horizontal movable assembly configured to move the chuck table and the emitter relatively in a horizontal direction, a calculating unit configured to calculate an etching amount to etch the wafer at an emitting position of the emitter, the emitter being locatable at the emitting position with the horizontal movable assembly, based on a difference between a thickness distribution of an entire surface of the wafer obtained in advance and a preset finishing thickness distribution, and a controller configured to control at least the chuck table, the emitter, and the horizontal movable assembly to etch the wafer by the etching amount calculated by the calculating unit.

According to the present disclosure, when the wafer has a part which is locally thicker than the other part, by calculating the emitting amount to emit the etching gas toward the wafer at the emitting position corresponding to the position where the thicker part is formed, and, further to the emitting amount, by calculating a distance of the emitter from the wafer in the vertical direction, the etching amount to etch the wafer may be increased at the locally thicker part of the wafer. Thereby, the wafer may be formed into the preset thickness form easily by etching the thicker part to the same thickness as the other part.

### BRIEF DESCRIPTION OF THE DRAWINGS

FIG. 1 is a schematic perspective view of a processing apparatus according to the present embodiment.

FIG. 2 is an enlarged illustrative view of an etching assembly.

FIG. 3 is an illustrative view of the processing apparatus including a controller.

FIGS. 4A-4B are illustrative views of a thickness-distribution obtaining step.

FIGS. 5A-5B are illustrative views of a calculating step.

FIGS. 6A-6B are illustrative views of an etching step.

FIG. 7 is a schematic perspective view of a modified example of the processing apparatus.

### DESCRIPTION OF EMBODIMENTS

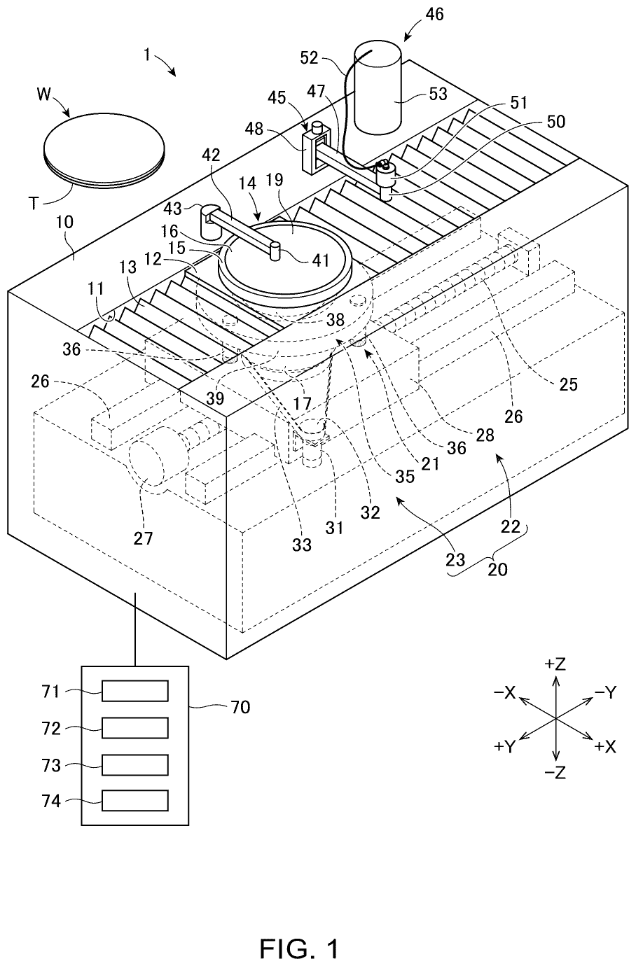

Hereinbelow, a processing apparatus according to the embodiment of the present disclosure will be described with reference to the accompanying drawings. FIG. 1 is a perspective view of a processing apparatus 1 according to the embodiment.

As shown in FIG. 1, the processing apparatus 1 is configured to etch a surface on one side of a wafer W, which is a workpiece formed substantially in a shape of a disk, to a preset thickness form. The wafer W is at least an etch-processible plate-formed workpiece and may be made of, for example, silicon such as Si, SiO₂, or SiN. The surface to be etched is the upper surface of the wafer W. A protective tape T is attached to the lower surface of the wafer W.

In the processing apparatus 1, an X-axis direction, a Y-axis direction, and a Z-axis direction are orthogonal to one another. The X-axis direction and the Y-axis direction are substantially horizontal directions, and the Z-axis direction is an up-down direction (vertical direction). A +X side and a −X side as pointed by a bidirectional arrow along the X-axis direction are a rightward side and a leftward side, respectively. A +Y side and a −Y side as pointed by a bidirectional arrow along the Y-axis direction are a frontward side and a rearward side, respectively. A +Z side and a −Z side as pointed by a bidirectional arrow along the Z-axis direction are an upper side and a lower side, respectively.

On an upper surface of a base 10 of the processing apparatus 1, an opening 11 in a rectangular form elongated in the Y-axis direction is formed. The processing apparatus 1 has a movable plate 12 that covers the opening 11, a waterproof cover 13 having a form of bellows, and a chuck table 14. The movable plate 12 and the waterproof cover 13 are movable along with the chuck table 14 in the Y-axis direction.

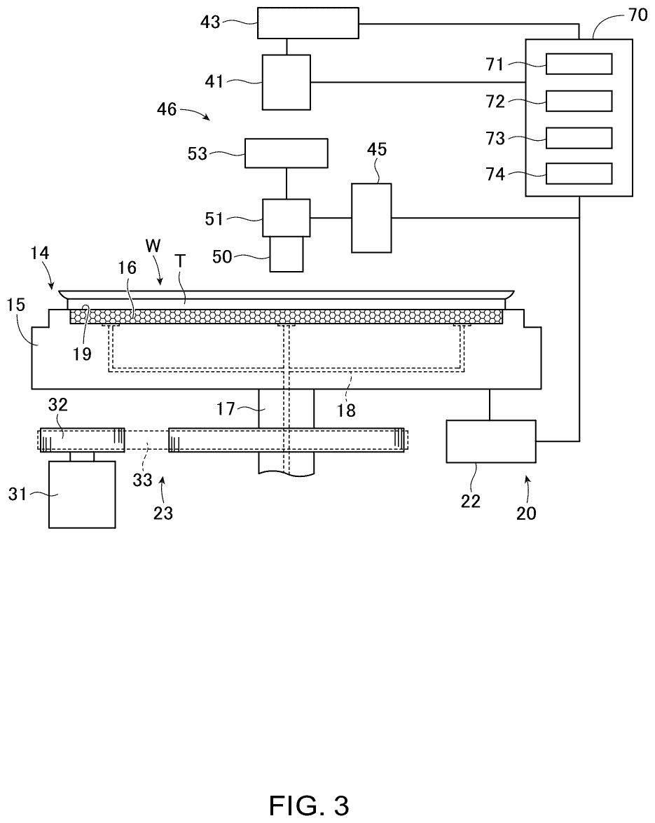

The chuck table 14 includes a frame 15, a porous sheet 16 fitted into a recess formed on an upper surface of the frame 15, and a chuck spindle 17 in a cylindrical form located below the frame 15. In the frame 15, a suction path 18 (see FIG. 3) is formed to connect a bottom of the recess, in which the porous sheet 16 is fitted, and a suction source (not shown), and the suction source being driven may produce a negative pressure on a surface (upper surface) of the porous sheet 16. The chuck table 14 may suction and hold the wafer W against a holder surface 19, which is formed of the surface of the porous sheet 16 and where the negative pressure is produced.

Below the waterproof cover 13, provided are a horizontal movable assembly 20, which may move the chuck table 14 in the horizontal direction, and a tilt-adjusting assembly 21, which may adjust an inclination of the chuck table 14. The horizontal movable assembly 20 includes a Y-axis movable assembly 22, which is a linear motion assembly, and a table rotating assembly 23.

The Y-axis movable assembly 22 is composed of, for example, an electric slider of a ball-screw style. The Y-axis movable assembly 22 includes a ball screw 25 and guide rails 26 extending in the Y-axis direction, a motor 27 connected to one end of the ball screw 25, and a slider 28 arranged slidably on the guide rails 26. On a lower surface of the slider 28, a nut, which is not shown, screwed with the ball screw 25 is formed. In the Y-axis movable assembly 22, the motor 27 may rotate to move the slider 28 in the Y-axis direction, and thereby the chuck table 14 supported by the slider 28 may move in the Y-axis direction.

The table rotating assembly 23 includes a motor 31, a belt pulley 32 provided to an output shaft of the motor 31, and a belt 33 wound around the belt pulley 32 and the chuck spindle 17. As the motor 31 drives the belt pulley 32 to rotate, the rotational force is transmitted to the chuck spindle 17 via the belt 33. Accordingly, the chuck spindle 17 may rotate, and the chuck table 14 may rotate on a central axis, which is parallel to the Z-axis.

The tilt-adjusting assembly 21 includes a supporting base 35, and position-adjusting units 36 and a fixed support (not shown), which are connected to the supporting base 35. The supporting base 35 includes a cylindrical portion 38, which is in a cylindrical shape and in which the chuck spindle 17 is inserted, and a flange portion 39, which is a part lower than the cylindrical portion 38 expanded radially in a shape of a disk. A bearing arranged inside the cylindrical portion 38 is in contact with an outer circumferential surface of the chuck spindle 17, and thereby the chuck spindle 17 is rotatably supported by the cylindrical portion 38 through the bearing. The tilt-adjusting assembly 21 may adjust the inclination of the chuck spindle 17 and the chuck table 14 by driving the position-adjusting units 36 and adjusting an inclination of the flange portion 39.

The processing apparatus 1 further includes a thickness measuring device 41, which is arranged on the base 10, to measure a thickness of the wafer W held on the chuck table 14. The thickness measuring device 41 may be, for example, a contactless-styled measuring device that may measure the thickness of the wafer W using measuring light or ultrasonic waves. The measuring device of the style using the measuring light may have a sensor to receive upper surface reflection light, which is the measuring light reflected off the upper surface of the wafer W, and lower surface reflection light, which is the measuring light reflected off the lower surface of the wafer W, and may measure the thickness of the wafer W in a spectral interference method based on a phenomenon that the upper surface reflection light and the lower surface reflection light interfere with each other. The measuring light may be, for example, laser light, or infrared SLD. The measuring device of the style using the ultrasonic waves may emit the ultrasonic waves from an upper side of the wafer W and receive ultrasonic vibrations reflected off the upper surface of the wafer W and ultrasonic vibrations reflected off the lower surface of the wafer W, thereby measuring the thickness of the wafer W based on a propagation time of the ultrasonic waves propagating through the wafer W.

The thickness measuring device 41 is supported by a distal end of a pivot arm 42, and a basal end of the pivot arm 42 is supported by the base 10 through a pivoting assembly 43 arranged on the upper surface of the base 10. The pivoting assembly 43 may move the pivot arm 42 to pivot about an axis, which is parallel to the Z-axis direction, and thereby the thickness measuring device 41 may be moved in the horizontal direction. More specifically, by driving the pivoting assembly 43, the thickness measuring device 41 may move between a position straight above the center of the chuck table 14 and an outer peripheral position. Therefore, while rotating the chuck table 14, by driving the pivoting assembly 43 to move the thickness measuring device 41 between the center of the chuck table 14 and the outer peripheral position, the thickness of the entire upper surface of the wafer W held on the chuck table 14 may be measured thoroughly, and the thickness distribution of the wafer W may be obtained.

The processing apparatus 1 further includes a lift/lower assembly 45 and an etching assembly 46 arranged on the base 10.

The lift/lower assembly 45 includes a supporting arm 47, which supports an emitter 50 of the etching assembly 46 at a distal end thereof, and a driving unit 48 to support a base of the supporting arm 47. The emitter 50 will be described further below. The supporting arm 47 supports the emitter 50 in an arrangement such that a position of the emitter 50 in the X-axis direction coincides with a position of the center of the chuck table 14 in the X-axis direction. Therefore, as the chuck table 14 is moved in the Y-axis direction, the emitter 50 may relatively pass through a position straight above a diameter of the holder surface 19 and a diameter of the wafer W that are parallel to the Y-axis direction.

The driving unit 48 may be composed of, but not necessarily limited to, for example, a cylinder, which may lift or lower the supporting arm 47 and the emitter 50 in the vertical direction, and a linear motor. As such, the driving unit 48 may lift or lower the chuck table 14 and the emitter 50 relatively to each other in the vertical direction.

The etching assembly 46 includes the emitter 50, a plasma generator 51 located above the emitter 50, and an etching gas feeder 53 to feed the plasma generator 51 with etching gas through a tube 52. The etching gas feeder 53 includes a container, which is located on the base 10 and stores an etching gas. The etching gas may be a halogen gas. In particular, while the wafer W is made of a silicon as described above, CF₄, CHF₃, or SF₆ may be used as the etching gas. Optionally, the etching gas may be mixed with O or H to promote radical generation to increase an etching amount. Further, optionally, noble gases such as He, Ne, or Ar may be included in the etching gas so that discharging of plasma may be easily maintained. Optionally, the emitter 50 may have a single emitting opening 55 or a plurality of emitting openings 55 that are arranged side by side. Preferably, the emitter 50 may be formed to have a cross-sectional diameter of 10 mm-30 mm.

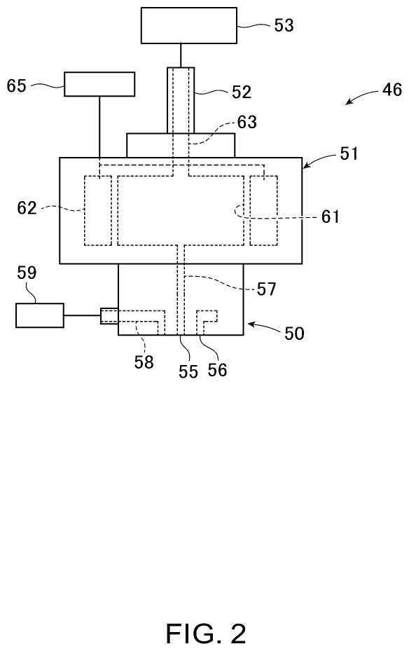

FIG. 2 is an enlarged view of the etching assembly 46. As shown in FIG. 2, the emitter 50 includes the emitter opening 55 formed at a lower end thereof, from which the plasma-activated etching gas may be emitted, and a suction opening 56 formed around the emitter opening 55. The emitter opening 55 is continuous with the plasma generator 51 through an emitter path 57. The suction opening 56 is continuous with a suction source 59 through a suction path 58. By driving the suction source 59, the etching gas emitted from the emitter opening 55 may be suctioned through the suction opening 56 and may be prevented from dispersing in the surrounding. Optionally, the suction opening 56 may include a plurality of suction openings arranged annularly on an outer circumference of the emitter opening 55 or may be in a form of a ring encircling the emitter opening 55.

The plasma generator 51 includes a chamber 61 that may store the etching gas, electrodes 62 located around the chamber 61, and a feeder path 63 continuous with the chamber 61. The feeder path 63 is continuous with the etching gas feeder 53 through the tube 52. As such, in the plasma generator 51, the etching gas is fed from the etching gas feeder 53 to the chamber 61.

The electrodes 62 are connected to a high-frequency power source 65. By a high-frequency voltage applied from the electrodes 62 to the etching gas stored in the chamber 61, the etching gas may be converted into a plasma state containing radicals. The plasma-activated etching gas may be emitted through the emitter path 57 from the emitter opening 55.

FIG. 3 is an illustrative view of the processing apparatus 1 according to the present embodiment. The processing apparatus 1 includes a controller 70 that may generally control the components in the processing apparatus 1. The controller 70 is composed of, for example, a processor to execute various processes and a memory. The controller 70 controls various operations including, for example, an operation to measure the thickness of the wafer W and an operation to etch the wafer W, according to controlling programs stored in the memory. More specifically, for example, the controller 70 may control an amount to etch the wafer W with the etching assembly 46, a moving speed of the horizontal movable assembly 20, an amount to emit the etching gas from the emitter 50 through a flow amount adjusting unit 72 which will be described further below, and driving of the lift/lower assembly 45. In the memory in the controller 70, data concerning processing of the wafer W, such as a thickness distribution of the entire upper surface of the wafer W and a finishing thickness distribution of the entire upper surface of the wafer W, is temporarily stored. In this context, the “finishing thickness distribution” corresponds to the “preset thickness form” before processing the wafer W and may mean, for example, a state of the wafer W having been etched evenly to a finishing thickness which equals an ideal value or an aimed value.

The controller 70 includes or is composed of a calculating unit 71, the flow amount adjusting unit 72, a storing unit 73, and a high-frequency power adjusting unit 74, which are illustrated as functional blocks in FIG. 3. These functional blocks are implemented by the controller 70 executing the programs stored in the memory in the controller 70. It may be noted that FIG. 3 illustrates merely the function blocks of the controller 70 related to the present disclosure, and the other function blocks are omitted.

The calculating unit 71 calculates a difference between the thickness distribution of the entire upper surface of the wafer W, which is obtained in advance through, for example, measurement with the thickness measuring device 41, and a preset finishing thickness distribution of the entire upper surface of the wafer W. Based on the calculated difference, the calculating unit 71 calculates an etching amount to etch the wafer W at an emitting position of the emitter 50 in the etching assembly 46. For this calculation, a calculation formula or a data table which defines a relation (e.g., proportional relation) between the calculated difference and the etching amount may be used.

The calculating unit 71 calculates an emitting amount to emit the etching gas toward the wafer W at the emitting position of the emitter 50 and a height (position in the Z-axis direction) with respect to the wafer W based on the calculated amount to etch the wafer W. Optionally, the emitting position of the emitter 50 with respect to the wafer W and the emitting amount of the etching gas at the emitting position may be calculated separately, and a process to associate the calculated results with each other may be performed. Further, the calculating unit 71 may calculate a relative emitting position in the horizontal direction (the X-axis and Y-axis directions) between the emitter 50 and the wafer W and a distance in the vertical direction (position in the Z-axis direction) between the emitter 50 and the wafer W in the relative emitting position based on the calculated amount to etch the wafer W. In the following paragraphs, the distance in the vertical direction between the emitter 50 and the wafer W may be referred to as “height of the emitter 50.”

The flow amount adjusting unit 72 is controlled to adjust the emitting amount of the etching gas to be emitted from the emitter 50 of the etching assembly 46. The adjustment of the emitting amount may include, for example, varying a total emitting duration to emit the etching gas toward the wafer W from the emitter 50 at the emitting position and varying an emitting amount of the etching gas at each emitting position. Further, optionally, the emitting amount at the emitting position may be controlled by varying a number of times to emit the etching gas at the emitting position.

The storing unit 73 obtains the thickness distribution of the entire upper surface of the wafer W based on measurement data concerning the thickness of the wafer W measured by the thickness measuring device 41 and driving conditions of the pivoting assembly 43 and the table rotating assembly 23. The thickness distribution may be set by, for example, positions on the entire upper surface of the wafer W in an XY coordinate system or angles around the center and positions in the radial direction of the wafer W.

The high-frequency power adjusting unit 74 is controlled to adjust the emitting amount of the etching gas to be emitted from the emitter 50 in the etching assembly 46. The adjustment of the emitting amount may include, for example, varying a voltage or an intensity of power to be applied from the high-frequency power source 65 to the electrodes 62 of the plasma generator 51.

For the operation of each component in the processing apparatus 1 described below, when no explicit entity is specified as a subject to control the operation, it is assumed that the operation is controlled by controlling signals output from the controller 70.

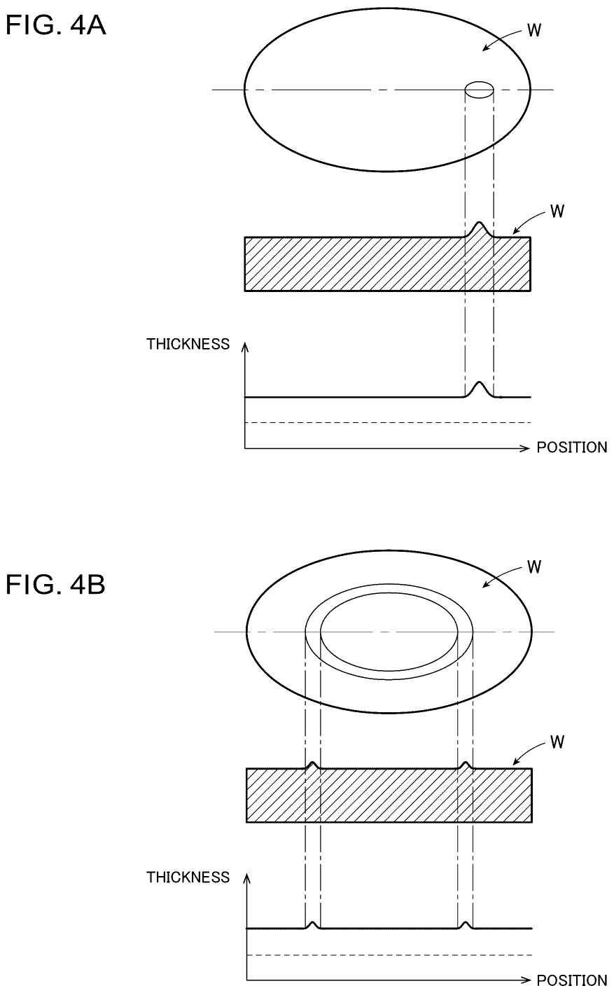

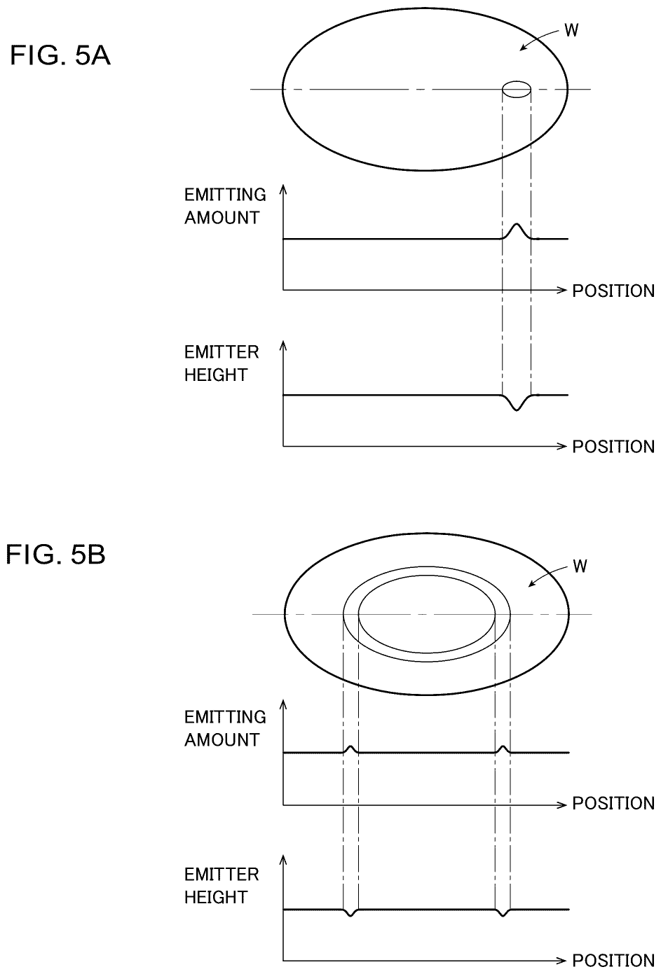

Next, a method to process the wafer W by etching the upper surface being one of the two surfaces of the wafer W into a preset thickness form will be described. The processing method includes a thickness distribution obtaining step, a calculating step, and an etching step, which are performed in this given order. FIGS. 4A-4B are illustrative views of the thickness distribution obtaining step, FIGS. 5A-5B are illustrative views of the calculating step, and FIGS. 6A-6B are illustrative views of the etching process.

In the following paragraphs, a method to process the wafer W, which is in a pre-process form shown in FIGS. 4A, 5A, and 6A, and the wafer W, which is in a pre-process form shown in FIGS. 4B, 5B, and 6B, will be described. The former wafer W is locally thicker at a point or at a part within a predetermined range on the upper surface. The latter wafer W is locally thicker in an annular range which is concentric with the wafer W. Note that the wafers W shown in FIGS. 4A-4B, 5A-5B, and 6A-6C are schematically illustrated in exaggerated forms, in which the locally thicker portions are emphasized.

### [Thickness Distribution Obtaining Step]

In the thickness distribution obtaining step, while the wafer W is suctioned and held against the chuck table 14, the Y-axis movable assembly 22 is driven to move the chuck table 14 in the Y-axis direction. As such, the chuck table 14 is located at a position where the center of the wafer W is located straight below the thickness measuring device 41.

In this state, the thickness measuring device 41 starts measuring the thickness of the wafer W. Meanwhile, the pivoting assembly 43 is operated to move the thickness measuring device 41 above the wafer W horizontally along the radial direction of the wafer W, and the table rotating assembly 23 is operated to rotate the chuck table 14 and the wafer W. Accordingly, the thickness measuring device 41 is moved along a swirly path relatively to the wafer W, and the thickness measuring device 41 measures either continuously or intermittently so that the thickness of the wafer W may be measured at a plurality of points in matrix or dispersedly throughout the upper surface of the wafer W. Optionally, the thickness measuring device 41 may measure the thickness of the wafer W along a concentric path with respect to the wafer W.

Measurement signals from the thickness measuring device 41 are output to the storing unit 73. Meanwhile, detection signals concerning a rotation speed and a rotation angle are output from detecting devices such as encoders (not shown) provided to a motor (not shown) in the pivoting assembly 43 and the motor 31 of the table rotating assembly 23 to the storing unit 73. The storing unit 73 obtains, based on the detection signals from the motors and the measurement signals from the thickness measuring device 41, the thickness distribution of the entire upper surface of the wafer W.

For example, in the case of the wafer W as shown in FIG. 4A or 4B, which includes a perspective view in a top row and a cross-sectional view in a middle row, a thickness distribution as represented in a graph shown in a bottom row may be obtained. In the graph shown in the bottom row, the horizontal axis corresponds to positions at the cross-section of the wafer W indicated in a dash-and-dot line in the top row, and the vertical axis corresponds to the thickness of the wafer W. As such, the thickness distribution represented in the graph as shown in FIG. 4A or 4B, where a thickness value increases at a position corresponding to the locally thicker portion, may be obtained.

### [Calculating Step]

After the thickness distribution obtaining step, the calculating step is performed based on the thickness distribution obtained in the thickness distribution obtaining step. In the calculating step, as shown in the graph in FIG. 4A or 4B, the calculating unit 71 calculates the difference between the thickness distribution (indicated in a solid line) of the entire upper surface of the wafer W, which is obtained in advance by the storing unit 73, and the finishing thickness distribution (indicated in a broken line) of the entire upper surface of the wafer W, which is set and stored in advance. In a case where the finishing thickness distribution is in a setting such that the upper surface and the lower surface of the wafer W are parallel, a calculation result such that the difference between the obtained (measured) thickness distribution and the finishing thickness distribution increases at the position corresponding to the locally thicker portion may be obtained.

In the calculating step, based on the difference calculated as above, the calculating unit 71 calculates an etching amount to etch the wafer W, which increases as the difference increases, at each position on the upper surface of the wafer W. The position on the upper surface of the wafer W corresponds to the emitting position where the emitter 50 emits the etching gas toward the upper surface. In other words, the etching amount to etch the wafer W is calculated in association with the emitting position of the emitter 50.

Further, in the calculating step, the calculating unit 71 calculates an emitting amount for the emitter 50 to emit the etching gas toward the wafer W at the emitting position according to the calculated etching amount. For example, in a case of the wafer W as shown in a perspective view in a top row in FIG. 5A or 5B, the emitting amount as shown in a graph in a middle row is calculated. In the graph shown in each of the middle rows in FIGS. 5A and 5B, the horizontal axis corresponds to positions at the cross-section of the wafer W indicated in a dash-and-dot line in the top row, and the vertical axis corresponds to the emitting amount to emit the etching gas. As such, the calculated result indicating a relation between the emitting amount and the position on the wafer W, where the emitting amount to emit the etching gas increases at a position corresponding to the locally thicker portion, may be obtained.

Furthermore, in the calculating step, the calculating unit 71 calculates a height of the emitter 50 (position in the Z-axis direction) for the emitter 50 to emit the etching gas toward the wafer W at the emitting position, according to the calculated etching amount. For example, in the case of the wafer W as shown in the perspective view in the top row in FIG. 5A or 5B, the height of the emitter 50 as shown in the graph in the bottom row is calculated. In the graph shown in each of the middle rows in FIGS. 5A and 5B, the horizontal axis corresponds to positions at the cross-section of the wafer W indicated in the dash-and-dot line in the top row, and the vertical axis corresponds to the height of the emitter 50. As such, the calculated result indicating a relation between the height of the emitter 50 and the position on the wafer W, where the height of the emitter 50 is reduced at a position corresponding to the locally thicker portion, may be obtained.

### [Etching Step]

After the calculating step, the etching step in which the wafer W is etched is performed. In the etching step, first, the Y-axis movable assembly 22 is driven to move the chuck table 14 in the Y-axis direction, and the chuck table 14 is located at a position where the center of the wafer W is located straight below the emitter 50 of the etching assembly 46.

In this setting, the plasma-activated etching gas is emitted at the wafer W held on the chuck table 14 from the emitter 50. Meanwhile, the horizontal movable assembly 20 is operated to move the chuck table 14 and the emitter 50 horizontally relatively to each other. In particular, the Y-axis movable assembly 22 is operated to move the chuck table 14 and the wafer W so that the emitter 50 is moved above the wafer W from the center toward the outer circumference of the wafer W while the table rotating assembly 23 is operated to rotate the chuck table 14 and the wafer W. Accordingly, the emitter 50 is moved along a swirly path relatively to the wafer W, and the plasma-activated etching gas is emitted at the entire upper surface of the wafer W held on the chuck table 14 from the emitter 50, thereby etching the wafer W.

Emission of the etching gas in the etching step is controlled by the controller 70 so that the amount of the etching gas to be emitted is equal to the etching amount calculated by the calculating unit 71 in the calculating step.

For example, the controller 70 may control the flow amount adjusting unit 72 to adjust the amount of the etching gas to be emitted according to the timing when the wafer W moving relatively to the emitter 50 passes through the emitting position of the emitter 50. The flow amount adjusting unit 72 may control the emitting amount to emit the etching gas from the emitter 50 of the etching assembly 46 using the relation between the emitting position of the emitter 50 with respect to the wafer W and the emitting amount of the etching gas calculated in the calculating step as shown in the graph in the middle row in each of FIGS. 5A and 5B. Under this control, the emitting amount of the etching gas may be changed relatively according to the thickness distribution of the wafer W in order to etch the wafer W to the preset thickness form. In particular, the emitting amount to emit the etching gas at the locally thicker part of the wafer W may be increased compared to the amount of the etching gas to be emitted at the other part of the wafer W. As such, the wafer W may be formed to an even thickness as shown in FIG. 6A or 6B.

For another example, the controller 70 may control the high-frequency power adjusting unit 74 to adjust the amount of the power (variable voltage control) to adjust the emitting amount of the etching gas according to the timing when the wafer W moving relatively to the emitter 50 passes through the emitting position of the emitter 50. The high-frequency power adjusting unit 74 may control the emitting amount to emit the etching gas from the emitter 50 of the etching assembly 46 using the relation between the emitting position of the emitter 50 with respect to the wafer W and the emitting amount of the etching gas calculated in the calculating step as shown in the graph in the middle row in each of FIGS. 5A and 5B. Under this control, the emitting amount of the etching gas may be changed relatively according to the thickness distribution of the wafer W in order to etch the wafer W to the preset thickness form. In particular, the emitting amount to emit the etching gas at the locally thicker part of the wafer W may be increased compared to the amount of the etching gas to be emitted at the other part of the wafer W. As such, the wafer W may be formed to the even thickness as shown in FIG. 6A or 6B.

Optionally, adjustment of the emitting amount of the etching gas may be controlled by the controller 70 changing the moving speed of the Y-axis movable assembly 22 and/or the rotating speed of the table rotating assembly 23 in the horizontal movable assembly 20. Under this control, a total emitting time at each emitting position to emit the etching gas may be changed relatively between the locally thicker part and the other part of the wafer W to etch the wafer W to the preset thickness form. Under this control, the emitting amount to emit the etching gas from the emitter 50 may be maintained constant, and the control of the etching assembly 46 may be simplified. However, this option may not necessarily hinder the emitting amount of the etching gas from being changeable.

For another example, under the control of the controller 70, the height of the emitter 50 may be adjusted according to the timing when the wafer W moving relatively to the emitter 50 passes through the position below the emitting position of the emitter 50. The controller 70 may control driving of the lift/lower assembly 45 using the relation between the emitting position of the emitter 50 with respect to the wafer W and the height of the emitter 50 calculated in the calculating step as shown in the graph in the bottom row in each of FIGS. 5A and 5B. Under this control, the height of the emitter 50 may be relatively changed according to the thickness distribution of the wafer W in order to etch the wafer W to the preset thickness form. In particular, the etching amount to etch the wafer W may be increased at the locally thicker part of the wafer W, compared to the other part in the wafer W, by lowering the position of the emitter 50 to locate the emitter 50 closer to the wafer W. As such, the wafer W may be etched to the even thickness as shown in FIG. 6A or 6B.

According to the embodiment described above, when the wafer W has a part which is locally thicker than the other part, the locally thicker part may be etched by a larger amount compared to the other part. In other words, the etching amount may be adjusted at any position of the wafer W according to the thickness of the wafer W, and the wafer W may be formed into the preset thickness form easily by, for example, etching the thicker part to the same thickness as the other part to equalize the thickness within the wafer W.

As shown in FIGS. 4A-4B and 5A-5B, while the wafer W may be locally thickened, the thickness distribution of the entire upper surface of the wafer W may be obtained by measuring with the thickness measuring device 41. Therefore, according to the obtained thickness distribution, the emitting amount of the etching gas or the height of the emitter 50 at each emitting position of the emitter 50 may be adjusted, and the wafer W may be formed into the preset thickness form easily.

Moreover, the calculating unit 71 may calculate the difference between the thickness distribution of the entire upper surface of the wafer W and the finishing thickness distribution and may calculate the etching amount, the emitting amount of the etching gas, the height of the emitter 50, and the high-frequency power amount at each emitting position of the emitter 50 based on the calculated difference. Accordingly, based on the calculated result, the horizontal movable assembly 20 and the lift/lower assembly 45 that may move the emitter 50, the high-frequency power adjusting unit 74, and the etching assembly 46 to emit the etching gas may be controlled, and the upper surface of the wafer W may be etched to the preset thickness form.

Meanwhile, embodiment of the present disclosure may not necessarily be limited to the configurations described above but may be modified in various ways. The sizes or the forms of the components illustrated in the accompanying drawings in the embodiment described above are not limited thereto but may be modified optionally within the scope of the effects of the present disclosure. Moreover, the embodiment may be modified optionally without departing from the scope of the object of the present disclosure.

In the embodiment described above, the emitting amount of the etching gas and the height of the emitter 50 are calculated in the calculating step; however, for example, either one of the emitting amount or the height of the emitter 50 may be calculated, and the etching amount of the wafer W may be controlled solely by the emitting amount or the height of the emitter 50.

For another example, controlling the etching amount in the etching step may not necessarily hinder the calculated emitting amount of the etching gas and the calculated height of the emitter 50 from both being controlled simultaneously.

Moreover, while the entire upper surface of the wafer W may be etched in the etching step described above, optionally, the upper surface of the wafer W may not necessarily be entirely etched but may be, for example, etched partially at spots where the thickness is greater.

Moreover, in the embodiment described above, the thickness distribution of the wafer W is obtained with use of the thickness measuring device 41 in the processing apparatus 1. However, if the thickness distribution is available in advance before the processing apparatus 1 is loaded with the wafer W, the processing apparatus 1 may not necessarily be equipped with the thickness measuring device 41.

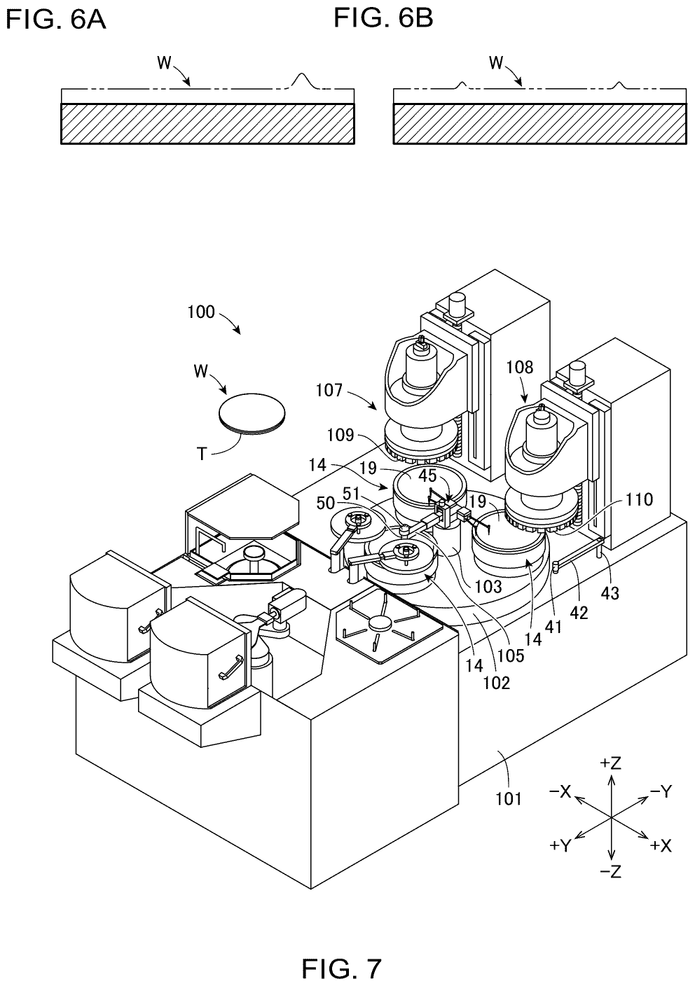

Moreover, the processing apparatus according to the present disclosure is not necessarily limited to the exemplary embodiment as described above but may be incorporated into another processing apparatus such as a grinding apparatus or a polishing apparatus. As a modified example of the processing apparatus, a grinding apparatus as shown in FIG. 7 may be suggested. FIG. 7 is a schematic perspective view of a processing apparatus 100 according to the modified example. In the description of the modified example below, items that are identical or equivalent to those described in the above embodiment may be referred to by the same reference sings, and description of those may be omitted or simplified.

The processing apparatus 100 according to the modified example shown in FIG. 7 includes three chuck tables 14 to hold wafers W. Each chuck table 14 is rotatable through a rotating assembly, which is not shown, on a central axis parallel to the Z-axis that extends through a center of the holder surface 19.

Moreover, the processing apparatus 100 includes a turntable 102, which is arranged on an upper surface of a base 101 and supports the three chuck tables 14, a supporting column 103 standing at a center of the turntable 102, and a lift/lower assembly 45 arranged on top of the supporting column 103. The turntable 102 is rotatable on a central axis, which is parallel to the Z-axis, and may move the three chuck tables 14 to locate one at a frontward position and the other two at rear-leftward and rear-rightward positions with respect to the center.

The lift/lower assembly 45 includes a supporting arm 105. The supporting arm 105 includes a driving assembly, which extends in parallel to the Y-axis and is expandable/contractable in the Y-axis direction. The supporting arm 105 supports the emitter 50 of the etching assembly (not shown) and the plasma generator 51 at a distal end thereof.

The emitter 50 is located above the one of the chuck tables 14 located frontward on the turntable 102. As such, by driving the lift/lower assembly 45, the chuck table 14 and the emitter 50 may ascend or descend relatively in the vertical direction. Moreover, by driving the supporting arm 105 to expand or contract and driving the chuck table 14 to rotate, the chuck table 14 and the emitter 50 may move relatively in the horizontal direction. In particular, as the supporting arm 105 expands or contracts, the emitter 50 above the wafer W is moved from the center of the wafer W toward the outer circumference in the radial direction while the table rotating assembly (not shown) is operated to rotate the chuck table 14 and the wafer W. Accordingly, the emitter 50 is moved along a swirly path relatively to the wafer W, and the plasma-activated etching gas is emitted from the emitter 50 at the entire upper surface of the wafer W held on the chuck table 14, thereby etching the wafer W.

The processing apparatus 100 includes a rough-grinding assembly 107, which is located leftward (toward the −X side) in a rearward area, and a finish-grinding assembly 108, which is located rightward (toward the +X side), on the base 101. The rough-grinding assembly 107 and the finish-grinding assembly 108 may grind the upper surfaces of the wafers W held on the chuck tables 14 with a plurality of rotating grindstones 109, 110, respectively. The grindstone 110 of the finish-grinding assembly 108 has a smaller grain diameter than that of the grindstone 109 of the rough-grinding assembly 107. The wafer W may be ground roughly by the rough-grinding assembly 107 and ground finely to be finished by the finish-grinding assembly 108.

The processing apparatus 100 includes the thickness measuring device 41, which is supported by the base 101 via the pivot arm 42 and the pivoting assembly 43. In the modified example shown in FIG. 7, as well as the embodiment described above, for measuring the thickness of the wafer W with the thickness measuring device 41, the chuck table 14 is rotated, and the pivoting assembly 43 is driven to move the thickness measuring device 41 between the center of the chuck table 14 and the outer peripheral position so that the thickness of the entire upper surface of the wafer W held on the chuck table 14 may be measured thoroughly, and the thickness distribution of the wafer W may be obtained.

In the processing apparatus 100 as shown in FIG. 7, as well as the above embodiment, the emitting position of the emitter 50 with respect to the wafer W, the emitting amount of the etching gas at the emitting position, and the height of the emitter 50 may be calculated and adjusted to etch the wafer W so that the wafer W may be formed to the preset thickness form. Moreover, according to the processing apparatus 100 shown in FIG. 7, the wafer W held on the chuck table 14 may be ground roughly by the rough-grinding assembly 107, ground finely to be finished by the finish-grinding assembly 108, thickness thereof may be measured by the thickness measuring device 41, and may be etched by the emitted etching gas. In other words, within the single processing apparatus 100, while the wafer W is held continuously on the chuck table 14, a series of the operations of rough-grinding, finish-grinding, thickness measuring, and etching may be performed automatically, and productivity may be improved.

As described above, the present disclosure is advantageous in that, when a wafer W has a part which is locally thicker than the other part, the wafer may be formed in a preset finishing thickness distribution easily.

1. A method for processing a wafer into a preset thickness form by emitting a plasma-activated etching gas from an emitter toward one side of the wafer to etch the one side of the wafer, comprising:
obtaining a thickness distribution of an entire surface on the one side of the wafer;
calculating a position where the emitter emits the etching gas toward the wafer and an emitting amount of the etching gas to be emitted at the emitting position based on a difference between the thickness distribution obtained and a preset finishing thickness distribution; and
emitting the etching gas of the etching amount at the etching position, the etching amount and the etching position having been calculated during the calculating, toward the one side of the wafer and etching the one side of the wafer to the preset thickness form.

2. The method according to claim 1, wherein the calculating further includes calculating a height of the emitter with respect to the wafer.

3. A processing apparatus comprising:
a chuck table configured to hold a wafer;
an emitter configured to emit a plasma-activated etching gas to etch the wafer held on the chuck table;
a horizontal movable assembly configured to move the chuck table and the emitter relatively in a horizontal direction;
a calculating unit configured to calculate an etching amount to etch the wafer at an emitting position of the emitter, the emitter being locatable at the emitting position with the horizontal movable assembly, based on a difference between a thickness distribution of an entire surface of the wafer obtained in advance and a preset finishing thickness distribution; and
a controller configured to control at least the chuck table, the emitter, and the horizontal movable assembly to etch the wafer by the etching amount calculated by the calculating unit.

4. The processing apparatus according to claim 3,
wherein the calculating unit is configured to calculate the emitting position, where the emitter emits the etching gas toward the wafer, in the horizontal direction and an emitting amount of the etching gas to be emitted by the emitter at the emitting position, and
wherein the controller is configured to control a moving speed of the horizontal movable assembly based on the emitting position and the emitting amount calculated by the calculating unit.

5. The processing apparatus according to claim 3, further comprising a lift/lower assembly configured to move the chuck table and the emitter relatively in a vertical direction,
wherein the calculating unit is configured to further calculate a height of the emitter with respect to the wafer, and
wherein the controller is configured to control the lift/lower assembly to locate the emitter at the calculated height.

6. The processing apparatus according to claim 3, further comprising a flow amount adjusting unit configured to adjust an amount of the etching gas to be emitted from the emitter by varying at least one of an emitting duration of the etching gas, an amount to emit the etching gas at each emitting position, or a number of times to emit the etching gas,
wherein the calculating unit is configured to calculate the emitting position, where the emitter emits the etching gas toward the wafer, in the horizontal direction and an emitting amount of the etching gas to be emitted by the emitter at the emitting position, and
wherein the controller is configured to control the flow amount adjusting unit based on the emitting position and the emitting amount calculated by the calculating unit.

7. The processing apparatus according to claim 3, further comprising a high-frequency power adjusting unit configured to adjust an amount of the etching gas to be emitted from the emitter by varying an intensity of power to be applied to the etching gas,
wherein the calculating unit is configured to calculate the emitting position, where the emitter emits the etching gas toward the wafer, in the horizontal direction and an emitting amount of the etching gas to be emitted by the emitter at the emitting position, and
wherein the controller is configured to control the high-frequency power adjusting unit based on the emitting position and the emitting amount calculated by the calculating unit.

8. The processing apparatus according to claim 3, further comprising:
a thickness measuring device configured to measure a thickness of the wafer held on the chuck table; and
a storing unit configured to obtain a thickness distribution of the entire surface of the wafer measured by the thickness measuring device.

9. The processing apparatus according to claim 3,
wherein the emitter includes an emitter opening configured to emit the etching gas there-through and a suction opening formed around the emitter opening.
